(19) United States
(12) Patent Application Publication
(10) Pub. No.: US 2022/0186845 A1
(43) Pub. Date: Jun. 16, 2022

(54) FLOW PATH ASSEMBLY, VALVE DEVICE, FLUID CONTROL DEVICE, SEMICONDUCTOR MANUFACTURING APPARATUS AND SEMICONDUCTOR MANUFACTURING METHOD USING SAID FLOW PATH ASSEMBLY

(71) Applicant: FUJIKIN INCORPORATED, Osaka (JP)

(72) Inventors: Toshiyuki INADA, Osaka (JP); Kazunari WATANABE, Osaka (JP); Kenji AIKAWA, Osaka (JP); Kohei SHIGYOU, Osaka (JP); Tomohiro NAKATA, Osaka (JP); Takahiro MATSUDA, Osaka (JP); Tsutomu SHINOHARA, Osaka (JP)

(73) Assignee: FUJIKIN INCORPORATED, Osaka (JP)

(21) Appl. No.: 17/425,424

(22) PCT Filed: Jan. 21, 2020
(86) PCT No.: PCT/JP2020/001955

§ 371 Date: Jul. 23, 2021

(30) Foreign Application Priority Data
Jan. 31, 2019 (JP) 2019-016228

(51) Int. Cl. F16K 7/16; F16K 27/02; H01L 21/67

(52) U.S. Cl. CPC F16K 7/16; H01L 21/67017; F16K 27/0236

(57) ABSTRACT

A first flow path member has a first sealing surface for supporting one end surface, in a central axis direction, of an annular seal member, and a second flow path member has a second seal surface including a flat surface for supporting a surface of a plate-like member, and a third seal surface for supporting an outer peripheral surface of the annular seal member, wherein: in the annular seal member, an other end surface of the annular seal member is pressed against the back surface of the plate-like member, the one end surface of the annular seal member is pressed against the first seal surface of the first flow path member, and the outer peripheral surface of the annular seal member is pressed against the third seal surface of the second flow path member; and the plate-like member is pressed by the other end surface of the annular seal member.

### TECHNICAL FIELD

The present invention relates to a flow path assembly, a valve device, a fluid control device, a semiconductor manufacturing method, and a semiconductor manufacturing apparatus using the valve device using the flow path assembly.

### BACKGROUND ART

In various manufacturing processes such as semiconductor manufacturing processes, a fluid control device in which various fluid devices such as an open-close valve, a regulator, a mass flow controller, and the like are integrated is generally used in order to supply accurately measured process gases to a processing chamber. In such a fluid control device as described above, integration is realized by arranging an installation block (hereinafter referred to as a base block) in which a flow path is formed along the longitudinal direction of a base plate instead of pipe joints, and installing a plurality of fluid devices including joint blocks to which pipe joints and a plurality of fluid devices are connected, and the like on the base block (for example, refer to Patent Literature 1).

### PATENT LITERATURE

PTL 1: Japanese Laid-Open Patent Application No. 2007-3013
PTL 2: Japanese Laid-Open Patent No. 4137267
PTL 3: Japanese Laid-Open Patent Application No. 2010-190430

### SUMMARY OF INVENTION

### Technical Problem

Control of the supply of process gases in various manufacturing processes requires higher responsiveness and requires that the fluid control device be as compact and integrated as possible and installed closer to the processing chamber to which the fluid is supplied.

Along with the increase in size of processing objects, such as the increase in size of the diameter of the semiconductor wafer, it becomes necessary to also increase the supply flow rate of the fluid supplied from the fluid control device into the processing chamber.

In addition, in order to improve the responsiveness of the supply control of process gases, shortening of the flow path is indispensable, and a technique of integrating functional components such as orifices and filters into valve bodies of valve devices has also been proposed (see Patent Literature 2, 3, etc.).

Thus, when functional components such as orifices and filters are integrated in a flow path of a valve body of a valve device, a technique for reliably sealing a space between a member defining the flow path and the functional components such as the orifice and the filter for a long period of time is required.

It is an object of the present invention to provide a flow path assembly incorporating functional components such as orifices and filters, wherein the functional components and the flow path components defining the flow path are reliably sealed for a long period of time.

It is another object of the present invention to provide a valve device in which the flow path assembly described above is incorporated in a valve body to form a part of the flow path.

Still another object of the present invention is to provide a fluid control device and a semiconductor manufacturing apparatus using the above-mentioned valve device.

### Solution to Problem

The flow path assembly of the present invention is a flow path assembly comprising a first flow path member and a metallic second flow path member made of metal defining fluid flow paths connected to each other via a connecting portion;

a plate-like member provided between the first flow path member and the second flow path member and having a functional portion providing a specific action on a fluid flowing through the fluid flow path, and

an annular seal member made of resin provided between the first flow path member and the second flow path member,

the first flow path member having a first sealing surface for supporting one end surface of the annular seal member,

the second flow path member having a second sealing surface that is a flat surface for supporting the surface of the plate-like member, and a third sealing surface for supporting the outer peripheral surface of the annular seal member,

wherein the annular seal member is crushed by a force acting between the first flow path member and the second flow path member by the connecting portion, the other end surface of the annular seal member is pressed against a back surface of the plate-like member air-tightly or liquid-tightly, the one end surface of the annular seal member is pressed against the first sealing surface of the first flow path member air-tightly or liquid-tightly, and the outer peripheral surface of the annular seal member is pressed against the third sealing surface of the second flow path member air-tightly or liquid-tightly, and

the plate-like member is pressed by the other end surface of the annular seal member so that the surface of the plate-like member is pressed against the second sealing surface of the second flow path member air-tightly or liquid-tightly.

The fluid control device of the present invention is a fluid control device comprising a plurality of fluid devices that are arranged,

the plurality of fluid devices including a valve device having the above configuration.

The semiconductor manufacturing apparatus of the present invention comprises using a valve device of the above configuration for controlling a flow rate of a process gas in a manufacturing process of a semiconductor device requiring a process step using the process gas in a sealed chamber.

The semiconductor manufacturing method of the present invention comprises using a valve device of the above configuration for controlling a flow rate of a process gas in a manufacturing process of a semiconductor device requiring a process step using the process gas in a sealed chamber.

### Advantageous Effects of Invention

According to the present invention, by crushing the seal member, the first, second and third sealing surfaces and the back surface of the plate-like member are sealed, so that a reliable sealing for a long period of time is provided.

### BRIEF DESCRIPTION OF DRAWINGS

FIG. 1A is a front view including a partial longitudinal section of a valve device according to a first embodiment of the present invention, in which a valve element is closed.

FIG. 1B is a front view including a partial longitudinal section of a valve device according to a first embodiment of the present invention, in which a valve element is opened.

FIG. 1C is a top view of the valve device according to the first embodiment of the present invention.

FIG. 1D is a bottom view of the valve device according to the first embodiment of the present invention.

FIG. 1E is a side view of the valve device according to the first embodiment of the present invention.

FIG. 2 is a cross-sectional view of an inner disk.

FIG. 3 is a cross-sectional view of a valve seat.

FIG. 4A is an enlarged cross-sectional view of a main part of the valve device according to the first embodiment of the present invention.

FIG. 4B is an enlarged cross-sectional view of a circle A in FIG. 4A.

FIG. 5 is a front view including a partial longitudinal section of a valve device according to a second embodiment of the present invention.

FIG. 6 is an enlarged cross-sectional view of the valve device according to the second embodiment of the present invention.

FIG. 7 is a schematic configuration diagram of a semiconductor manufacturing apparatus according to an embodiment of the present invention.

FIG. 8 is an external perspective view showing an example of a fluid control device.

### DESCRIPTION OF EMBODIMENTS

Embodiments of the present invention will be described below with reference to the drawings. In the present specification and the drawings, the same reference numerals are used to denote components having substantially the same functions, and thus repetitive descriptions thereof are omitted.

Arrows A1 and A2 shown in the drawings indicate the vertical direction, and arrow A1 indicates the upward direction and arrow A2 indicates the downward direction. Arrows B1 and B2 shown in the drawings indicate longitudinal directions of the valve body 20 of the valve device 1, and arrow B1 indicates one end side and arrow B2 indicates the other end side. Arrows C1 and C2 shown in the drawings indicate the width directions orthogonal to the longitudinal directions B1 and B2 of the valve body 20, arrow C1 indicates the front side and arrow C2 indicates the back side.

### Embodiment 1

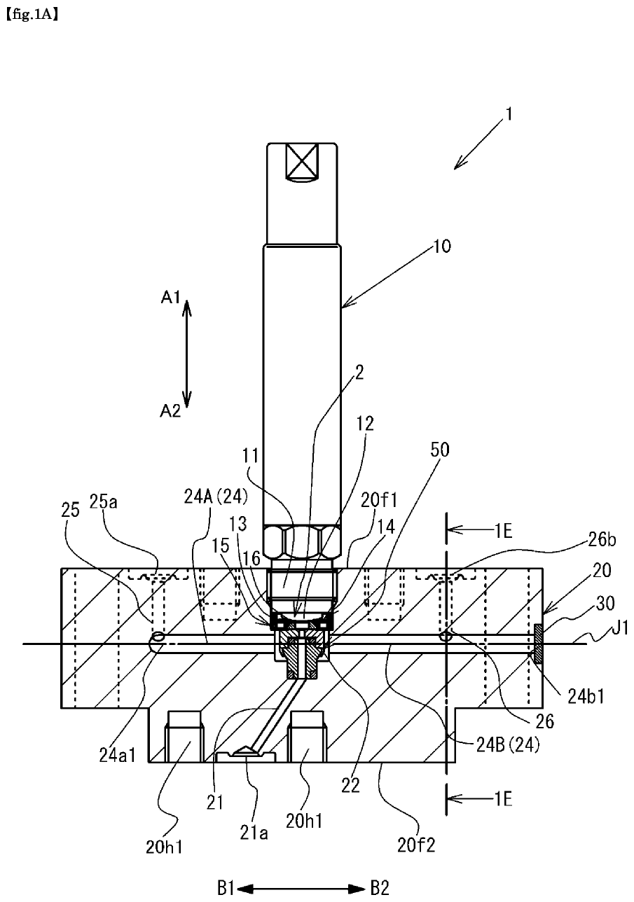

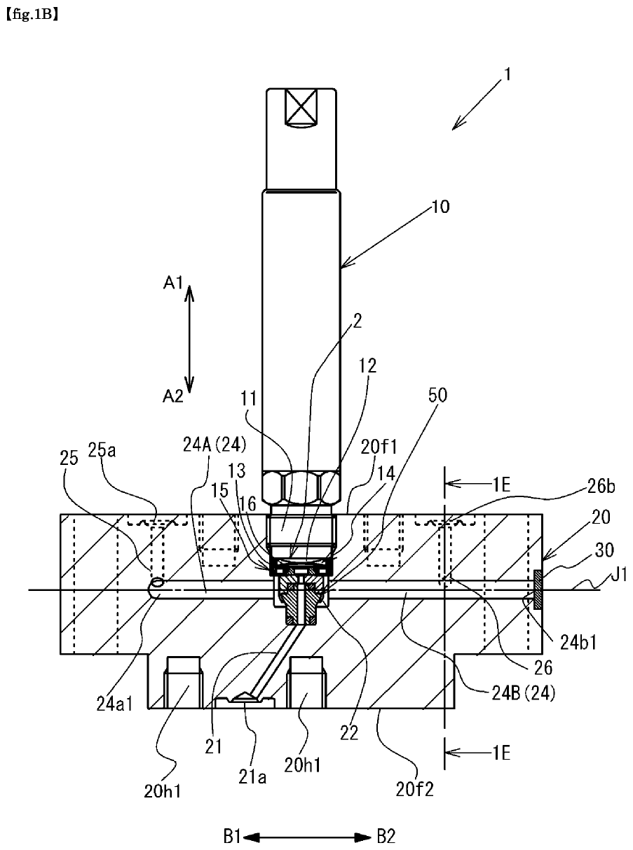

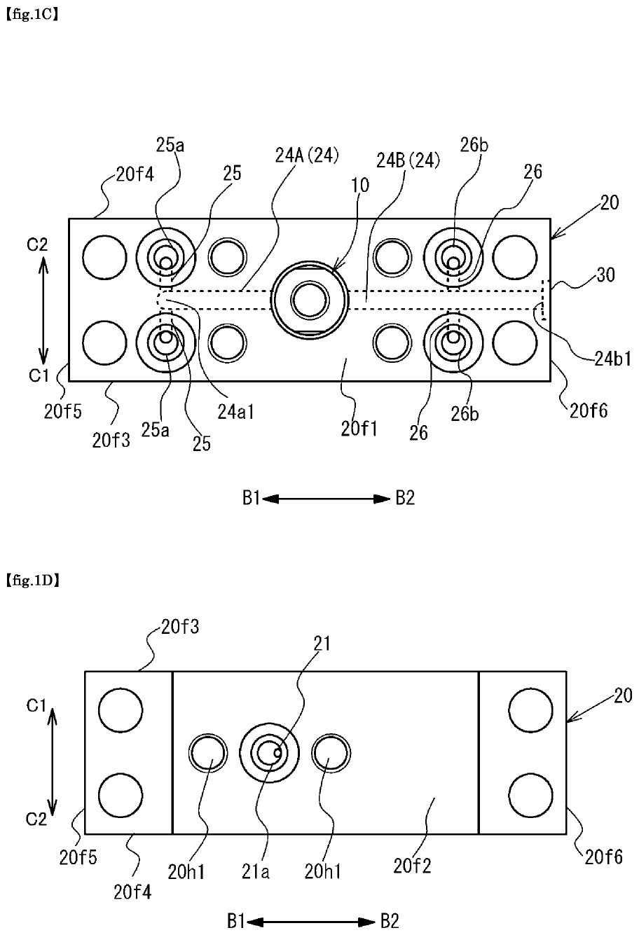

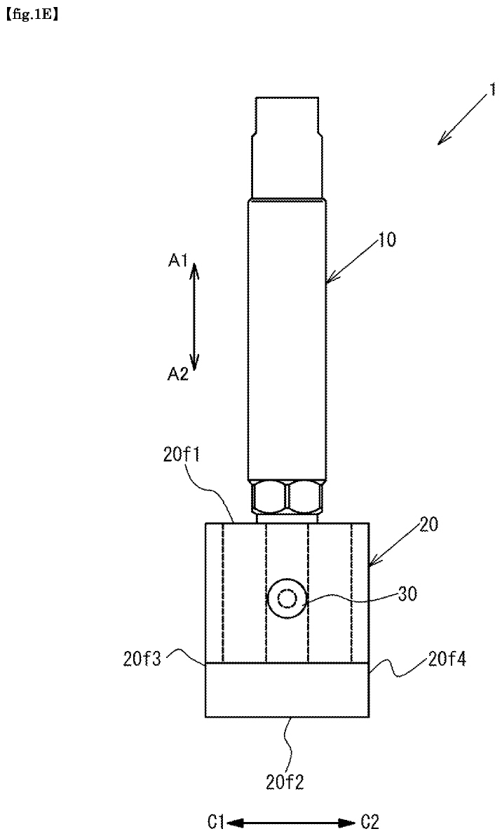

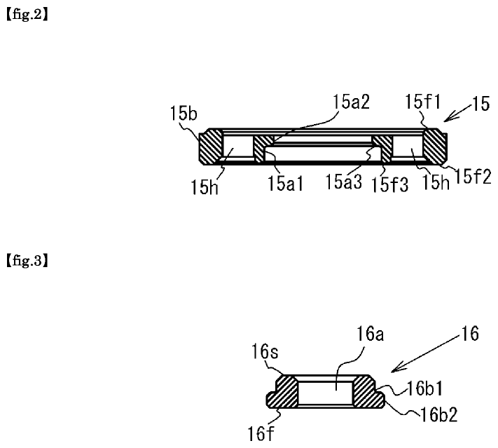

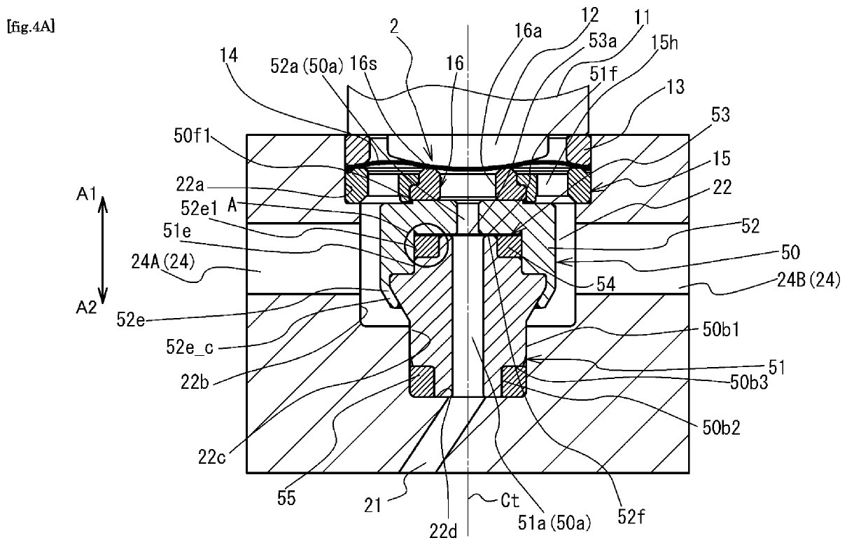

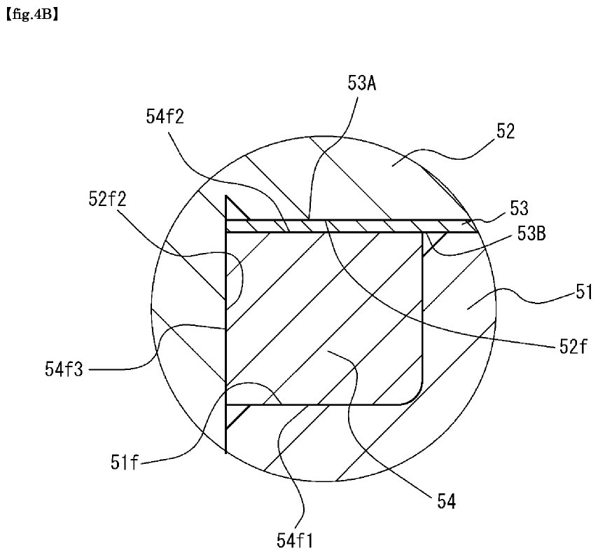

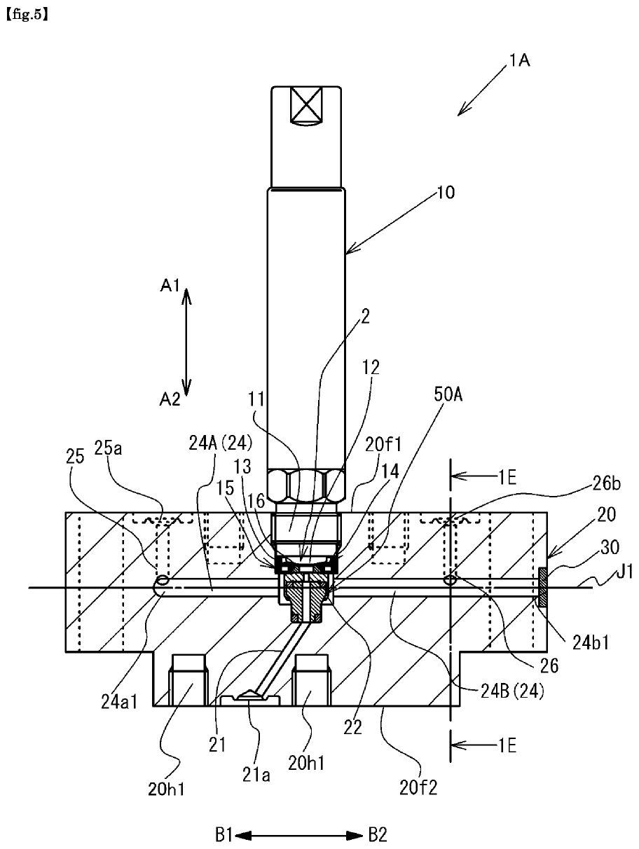

FIGS. 1A to 1E show examples of the structure of the valve device 1 according to the first embodiment. FIG. 2 shows an example of the cross-sectional structure of the inner disk of the valve device 1. FIG. 3 shows an example of the cross-sectional structure of the valve seat of the valve device 1. FIG. 4A shows an enlarged cross-section of the main part of the valve device 1. FIGS. 1A and 1B show the operation of the valve device 1. FIG. 1A shows the state in which the valve element is closed, and FIG. 1B shows the state in which the valve element is open.

The valve body 20 is a block-shaped member having a rectangular shape in a top view. The valve body 20 is defined by a top surface 20f1, a bottom surface 20f2, and four side surfaces 20f3 to 20f6 extending between the top surface 20f1 and the bottom surface 20f2. In addition, it defines an accommodation recess 22 which opens at the top surface 20f1. A valve element 2, which will be described later, is incorporated in the accommodation recess 22.

As can be seen from FIG. 4A and the like, the accommodation recess 22 has inner peripheral surfaces 22a, 22b, and 22c having different diameters and a bottom surface 22d. The diameters of the inner peripheral surfaces 22a, 22b, and 22c decrease in this order.

The valve body 20 defines a primary flow path 21 and secondary flow paths 24A, 24B connected to the accommodation recess 22. The primary flow path 21 is a flow path on a side to which a fluid such as a gas is supplied from the outside. The secondary flow paths 24A, 24B are flow paths that allows a fluid such as a gas flowing in from the primary flow path 21 through the valve element 2 to flow out to the outside.

The primary flow path 21 is formed to be inclined with respect to the bottom surface 20f2 of the valve body 20, and has one end connected to the bottom surface 22d of the accommodation recess 22, and the other end opened at the bottom surface 20f2.

A seal holding portion 21a is formed around the opening on the bottom surface 20f2 side of the primary flow path 21. In the seal holding portion 21a, a gasket is disposed as a seal member. The valve body 20 is connected to another flow path block (not shown) by screwing a fastening bolt into the screw hole 20h1. At this time, since the gasket held by seal holding portion 21a is crushed between the gasket and another flow path block (not shown) by the fastening force of the fastening bolt, the periphery of the opening on the bottom surface 20f2 side of the primary flow path 21 is sealed.

Examples of the gasket include gaskets made of metal or resin. Examples of the gasket include a soft gasket, a semi-metal gasket, and a metal gasket. Specifically, the following is suitably used.

(1) Soft gasket
Rubber O-ring
Rubber seat (for full seating)
Joint sheet
Expanded graphite sheet
PTFE sheets
PTFE jacketed type
   (2) Semi-metal gasket
Spiral-wound gasket
Metal jacket gasket
   (3) Metal gasket
Solid-metal flat gasket
Metal hollow O-ring
Ring joint

The same applies to the seal holding portions 25a, 26b provided around the openings of the branch flow paths 25, 26, which will be described later, and detailed description thereof is omitted.

The secondary flow path 24 includes two secondary flow paths 24A, 24B formed on opposite sides with each other across the accommodation recess 22 in the longitudinal directions B1, B2 of the valve body 20. The secondary flow paths 24A, 24B are formed on a common axis J1 extending in the longitudinal directions B1 and B2 of the valve body 20.

One end of the secondary flow path 24A is opened at the inner peripheral surface 22b of the accommodation recess 22, and the other end 24a1 is closed inside the valve body 20.

One end of the secondary flow path 24B is opened at the inner peripheral surface 22b of the accommodation recess 22, and the other end 24b1 is opened at the side surface 20f6 side.

The opening of the side surface 20f6 of the secondary flow path 24B is provided with a blocking member 30 by means of welding or the like, and the opening of the secondary flow path 24B is blocked.

The secondary flow path 24 can be easily formed by machining using a tool such as a drill.

In the valve device 1 according to the present embodiment, a fluid such as a gas flowing into the primary flow path 21 can be divided into four by the branch flow paths 25, 26 of the secondary flow path 24.

Each of the valve elements 2 has a diaphragm 14, an inner disk 15, a valve seat 16, and a valve seat support 50 composed of a flow path assembly, which will be described later. Hereinafter, the valve seat support 50 will also be referred to as a flow path assembly 50.

As shown in FIG. 4, the outer peripheral surface 50b1 of the valve seat support 50 is fitted and inserted into the inner peripheral surface 22c of the accommodation recess 22. The flow path assembly constituting the valve seat support 50 will be described in detail later. In the valve seat support 50, a detour passage 50a is formed at the center, and an annular support surface 50f1 centered on the detour passage 50a is formed at the upper end surface. The support surface 50f1 of the valve seat support 50 is a flat surface, and a step is formed on an outer peripheral portion of the support surface 50f1. The outer peripheral surface 50b1 of the valve seat support 50 has a diameter to fit into the inner peripheral surface 22c of the accommodation recess 22, and there is a step between the outer peripheral surface 50b2 which is reduced in diameter of the lower end side. An annular end surface 50b3 is formed by the step. As shown in FIG. 4 or the like, a second seal member 55 made of a resin such as PTFE or the like is fitted into the outer peripheral surface 50b2.

The second seal member 55 is formed to have a rectangular cross-sectional shape and has such a size that it is crushed between the bottom surface 22d of the accommodation recess 22 and the end surface 50b3 of the valve seat support 50. When the second seal member 55 is crushed between the bottom surface 22d of the accommodation recess 22 and the end surface 50b3 of the valve seat support 50, resin enters between the outer peripheral surface 50b2 of the valve seat support 50 and the inner peripheral surface 22c and the bottom surface 22d of the accommodation recess 22, and the gap between the valve seat support 50 and the accommodation recess 22 is reliably sealed. That is, the outer peripheral surface 50b2 and the end surface 50b3 serving as sealing surfaces cooperate with the inner peripheral surface 22c and the bottom surface 22d of the accommodation recess 22 to block the communication between the primary flow path 21 and the secondary flow path 24.

The detour passage 50a of the valve seat support 50 is connected to the primary flow path 21 that opens at the bottom surface 22d of the accommodation recess 22.

A valve seat 16 is provided on a support surface 50f1 of the valve seat support 50.

The valve seat 16 is formed of a resin such as PFA or PTFE so as to be elastically deformable, and, as shown in FIG. 3, the valve seat 16 is formed in an annular shape, and an annular seating surface 16s is formed on one end surface, and an annular sealing surface 16f is formed on the other end surface. Inside the seating surface 16s and the sealing surface 16f, a flow passage 16a that is a through hole is formed. The valve seat 16 has a small diameter portion 16b1 and a large diameter portion 16b2 on the outer peripheral side thereof, and a step portion is formed between the small diameter portion 16b1 and the large diameter portion 16b2.

The valve seat 16 is positioned with respect to the support surface 50f1 of the valve seat support 50 by the inner disk 15 as a positioning and pressing member, and is pressed toward the support surface 50f1 of the valve seat support 50 with a predetermined pressing force. Specifically, a large diameter portion 15a1 and the small diameter portion 15a2 formed in the center portion of the inner disk 15 are formed, and a step surface 15a3 is formed between the large diameter portion 15a1 and the small diameter portion 15a2. An annular flat surface 15f1 is formed on one end surface side of the inner disk 15. An annular flat surface 15f2 is formed on the outer side on the other end surface side of the inner disk 15, and an annular flat surface 15f3 is formed on the inner side. The flat surface 15f2 and the flat surface 15f3 have different heights, and the flat surface 15f3 is positioned closer to the flat surface 15f1.

An outer peripheral surface 15b that fits into the inner peripheral surface 22a of the accommodation recess 22 is formed on the outer peripheral side of the inner disk 15. Furthermore, a plurality of flow paths 15h passing from one end surface to the other end surface is formed at equal intervals in the circumferential direction. The large diameter portion 16b2 and the small diameter portion 16b1 of the valve seat 16 are fitted to the large diameter portion 15a1 and the small diameter portion 15a2 of the inner disk 15, whereby the valve seat 16 is positioned with respect to the support surface 50f1 of the valve seat support 50.

The flat surface 15f2 of the inner disk 15 is disposed on a flat step surface formed between the inner peripheral surface 22a and the inner peripheral surface 22b of the accommodation recess 22. A diaphragm 14 is disposed on a flat surface 15f1 of the inner disk 15, and a holding ring 13 is disposed on the diaphragm 14.

The actuator 10 is driven by a driving source such as a pneumatic pressure and drives the diaphragm presser 12 movably held in the vertical directions A1 and A2. As shown in FIG. 1A, the tip end portion of the casing 11 of the actuator 10 is screwed into and fixed to the valve body 20. The tip end portion presses the holding ring 13 in downward direction A2, and the diaphragm 14 is fixed in the accommodation recess 22. The diaphragm 14 seals the accommodation recess 22 on the opening side. In addition, the inner disk 15 is also pressed in downward direction A2. The height of the stepped surface 15a3 is set so that the stepped surface 15a3 presses the valve seat 16 toward the support surface 50f1 of the valve seat support 50 in a state in which the flat surface 15f2 of the inner disk 15 is pressed against the step surface of the accommodation recess 22. Further, the flat surface 15f3 of the inner disk 15 does not abut against the upper end surface of the valve seat support 50.

The diaphragm 14 has a diameter larger than the diameter of the valve seat 16, and is formed of a metal such as stainless steel and a NiCo based alloy, or fluorinated resin in a spherical shell shape so as to be elastically deformable. The diaphragm 14 is supported by the valve body 20 so as to be able to abut against and separate from the seating surface 16s of the valve seat 16.

In FIG. 4A, the diaphragm 14 is pressed and elastically deformed by the diaphragm presser 12, and is pressed against the seating surface 16s of the valve seat 16. The valve element 2 is in a closed state.

When the diaphragm 14 is pressed against the seating surface 16s of the valve seat 16, the flow path between the primary flow path 21 and the secondary flow path 24 is closed. When the diaphragm 14 of the valve element 2 is released from being pressed by the diaphragm presser 12, the valve element 2 is restored to a spherical shell shape as shown in FIG. 1B. When the diaphragm presser 12 is moved upward A1, the diaphragm 14 moves away from the seating surface 16s of the valve seat 16, as shown in FIG. 1B. Then, a fluid such as a process gas supplied from the primary flow path 21 flows through a gap between the diaphragm 14 and the seating surface 16s of the valve seat 16 into the secondary flow path 24. The fluid eventually flows out of the valve body 20 through the branch flow paths 25, 26. That is, the fluid is divided into four.

FIG. 4A illustrates an enlarged view of an example of a configuration of a flow path assembly constituting the valve seat support 50, which is a main part of the valve device 1. The flow path assembly 50 will be described with FIG. 4A.

The flow path assembly 50 includes flow path members 51 and 52, an orifice plate 53 that is a plate-like member provided between the flow path members 51 and 52, and an annular first seal member 54 that is a resin-made annular seal member provided under the orifice plate 53.

The orifice plate 53 is a disk-shaped member made of metal, and an orifice 53a is formed at the center. The orifice 53a is provided to allow a fluid flowing through the fluid flow paths 51a and 52a to pass therethrough. The orifice 53a acts as a resistance to fluid flow and creates a pressure difference between the fluid flow path 51a side and the fluid flow path 52a side.

The Flow path members 51 and 52 and the orifice plate 53 may be formed of the same type of metal material such as a stainless steel alloy or may be formed of different metal materials. In addition, in the present embodiment, the orifice plate 53 is used, but the present invention is not limited to this, and for example, a filter plate can be used.

The outer peripheral surface 51e on the upper end side of the flow path member 51 and the inner peripheral surface 52e1 arranged to the cylindrical portion 52e of the flow path member 52 are formed so as to fit with each other, whereby, the central axis Ct of the fluid flow paths 51a and 52a are aligned.

The flow path member 51 and the flow path member 52 are formed with annular opposing surfaces facing each other. The opposing surfaces are formed around the openings of the fluid flow paths 51a and 52a, and are arranged coaxially with the central axis Ct of the fluid flow paths 51a and 52a.

FIG. 4B shows an enlarged cross-sectional view inside the circle A of FIG. 4A.

As shown in FIG. 4A and FIG. 4B, the flow path member 51 has a first sealing surface 51f for supporting one end surface 54f1 in the central axis Ct direction of the first seal member 54.

The flow path member 52 defines a second sealing surface 52f that is a flat surface supporting the surface 53A of the orifice plate 53 and a third sealing surface 52f2 that supports the outer peripheral surface 54f3 of the first seal member 54. The second sealing surface 52f and the third sealing surface 52f2 are in an orthogonal relationship, and the first sealing surface 51f and the third sealing surface 52f2 are in an orthogonal relationship.

The first seal member 54 has a dimension longer than the distance between the first sealing surface 51f and the back surface 53B of the orifice plate 53 in a state before a caulking portion 52e_c undergoes plastic deformation. When the caulking portion 52e-c undergoes plastic deformation, the first seal member 54 is crushed by a force acting between the flow path member 51 and the flow path member 52.

When the first seal member 54 is crushed, the other end surface 54f2 of the first seal member 54 is pressed against the back surface 53B of the orifice plate 53 air-tightly or liquid-tightly.

At the same time, one end surface 54f1 of the first seal member 54 is pressed against the first sealing surface 51f of the flow path member 51 air-tightly or liquid-tightly, and the outer peripheral surface 54f3 of the first seal member 54 is pressed against the third seal surface 52f2 of the flow path member 52 air-tightly or liquid-tightly.

Furthermore, the orifice plate 53 is pressed by the other end surface 54f2 of the first seal member 54, and the surface 53A of the orifice plate 53 is pressed against the second sealing surface 52f of the flow path member 52 air-tightly or liquid-tightly.

When the first seal member 54 is crushed, all of paths that potentially cause leakage are sealed, and the first seal member 54 is directly or indirectly involved in sealing all of these paths that potentially cause leakage.

The first seal member 54 is formed of a resin material such as, but not limited to, a PEEK resin (polyetheretherketone) or a polyimide resin.

When the two flow path members and the orifice plate are made of metal, it is common to provide an annular protrusion and crushing it using the connecting force of the two flow path members to provide a seal. However, leakage may occur in this seal portion and the fluid may flow out to the outside.

In contrast, in the construction of the present embodiment, the first seal member 54 is directly or indirectly involved in all the seals, thereby providing a more reliable seal.

Further, since a reliable seal is provided by the first seal member 54, the surfaces of the flow path member 51 and 52 for supporting the orifice plate 53 can be made flat, and such surfaces are easily compatible with the plate-like member having other functions.

Further, since the orifice plate 53 does not need to be crushed, the desired flow rate can be provided without the influence of deformation or the like on the orifice 53a.

### Embodiment 2

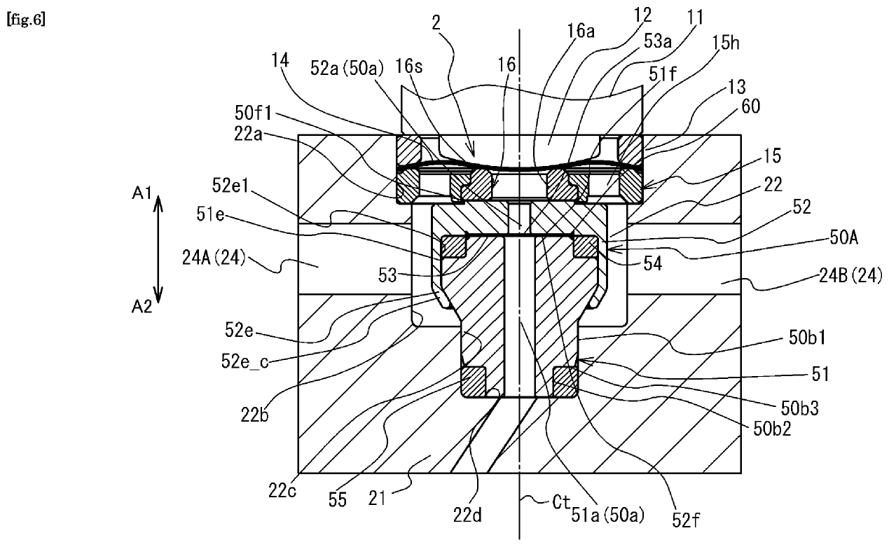

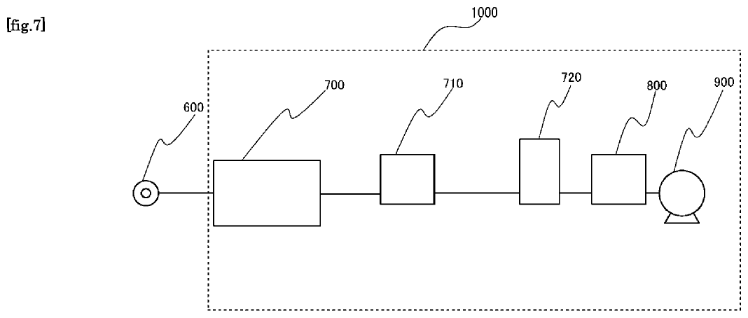

FIG. 5 shows an example of the configuration of a valve device 1A according to the second embodiment of the present invention. FIG. 6 shows an enlarged cross-section of the main part of the valve device 1A. Specifically, FIG. 6 shows an enlarged view of an example of the configuration of a flow path assembly constituting a valve seat support 50A which is a main part of the valve device 1A.

Incidentally, the basic configuration of the valve device 1A is the same as the valve device 1 according to the first embodiment. Further, in the second embodiment, the differences from the first embodiment will be mainly described, and the same portions as those in the first embodiment will be denoted by the same reference numerals. Further, modified examples applied to some portion of the first embodiment is also applied to the same portion of the second embodiment in the same manner.

The flow path assembly 50A includes flow path members 51 and 52, an orifice plate 53 that is a plate-like member provided between the flow path members 51 and 52, and an annular first seal member 54 interposed between the flow path members 51 and 52.

The outer peripheral edge portion of the orifice plate 53 is welded to the second sealing surface 52f that is a flat surface of the flow path member 52. The welded portion is shown in FIG. 6 as a weld portion 60. The second sealing surface composed of flat surfaces includes not only a single plane but also a flat surface composed of a plurality of flat surfaces. The other end surface 54f2 of the first seal member 54 is pressed against the second sealing surface 52f of the flow path member 52 air-tightly or liquid-tightly.

In the flow path assembly 50A, the sealing by the first seal member 54 and the weld portion 60 can reliably prevent the fluid from flowing out.

Although the embodiment of the present invention has been described by dividing the 2 embodiments, the present invention is not limited to the respective embodiments described above. Various additions, modifications, or the like can be made by those skilled in the art within the scope of the present invention.

In the above embodiments, the cases where the secondary flow path 24 is branched into a plurality in the valve body 20 and the branch flow paths 25 and 26 open at the top surface 20f1 of the valve body 20 have been exemplified, but the present invention is not limited thereto, and a configuration in which they open at the bottom surface 20f2 or any of the side surfaces 20f3 to 20f6 can be also adopted.

In the above embodiments, the inner disk 15 and the valve seat 16 are separate members, but it is also possible to integrate the inner disk 15 and the valve seat 16.

In the above embodiments, the flow path 21 is the primary side and the flow paths 24A and 24B are the secondary side, but the present invention is not limited thereto, and the flow path 21 may be the secondary side and the flow paths 24A and 24B may be the primary side.

In the above embodiments, the cases where the flow path assembly is used as the valve seat support are exemplified, but the present invention is not limited thereto, and can be applied to a flow path other than a valve device.

In the above embodiments, the orifice plate is exemplified as the plate-like member, but the present invention is not limited thereto, and for example, a filter plate having a filter function portion may be employed as the plate-like member.

In the above embodiments, the orifice plate 53 is welded to the flow path member 52, but it can also be welded to the flow path member 51.

Next, referring to FIG. 7, an application example of the valve device 1 or the valve device 1A described above will be described. The valve device 1 or the valve device 1A described above is applied to and used in the semiconductor manufacturing apparatus and the fluid control device described below.

A semiconductor manufacturing apparatus 1000 shown in FIG. 7 uses the valve device 1 to control the flow rate of a process gas in a semiconductor device manufacturing process that requires a processing step with the process gas in a sealed chamber (processing chamber 800). For example, the semiconductor manufacturing apparatus 1000 shown in FIG. 7 is a system for performing a semiconductor manufacturing process using atomic layer deposition (ALD: Atomic Layer Deposition method), where 600 is a process gas source, 700 is a gas box, 710 is a tank, 800 is a processing chamber, 900 is an exhaust pump.

In a processing process that deposits a film on a substrate, in order to stably supply a process gas, a process gas supplied from the gas box 700 is temporarily stored in the tank 710 as a buffer, and a valve 720 provided in the immediate vicinity of the processing chamber 800 is opened and closed at high frequency to supply the process gas from the tank to the processing chamber of a vacuum atmosphere.

The ALD method is one of chemical vapor deposition methods, in which two or more types of process gases are alternately flowed on the substrate surface under film forming conditions such as temperature and time to react with atoms on the substrate surface to deposit a film layer by layer. This method allows control of each atom layer, making it possible to form a uniform film thickness and grow the film very finely, even in terms of film quality.

In the semiconductor manufacturing process by the ALD method, it is necessary to precisely adjust the flow rate of the treatment gas (process gas), and it is also necessary to secure the flow rate of the process gas to some extent along with increase in the diameter of the substrate or the like.

The gas box 700 houses a fluid control device in which various fluid devices are integrated in order to supply the precisely weighed process gas to the processing chamber 800. The fluid control device is an array of a plurality of fluid devices.

The tank 710 functions as a buffer for temporarily storing the process gas supplied from the gas box 700.

The processing chamber 800 provides a sealed processing space for forming a film on a substrate by an ALD method.

The exhaust pump 900 draws a vacuum in the processing chamber 800.

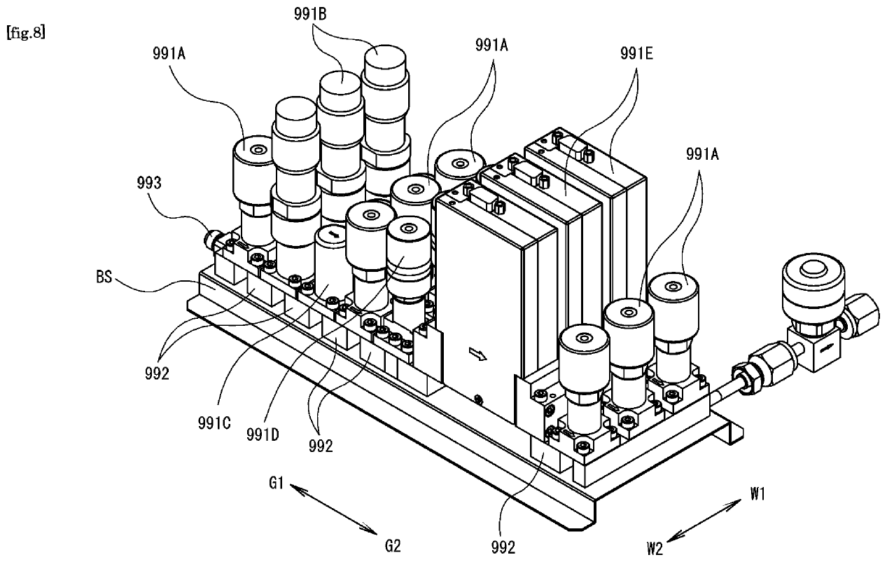

Referring to FIG. 8, an exemplary fluid control device to which the valve device of the present invention is applied will be described.

The fluid control device shown in FIG. 8 is provided with a metallic base plate BS arranged along the widthwise directions W1, W2 and extending in the longitudinal directions G1, G2. Note that W1 represents the front side, W2 represents the back side, G1 represents the upstream side, and G2 represents the downstream side. Various fluid devices 991A to 991E are installed on the base plate BS via a plurality of flow path blocks 992, and a flow path (not shown) through which fluid flows from the upstream side G1 toward the downstream side G2 is formed by the plurality of flow path blocks 992.

Here, a “fluid device” is a device used in a fluid control device for controlling a flow of a fluid, and includes a body defining a fluid flow path, and has at least two flow path ports opening at a surface of the body. Specific examples include, but are not limited to, an open-close valve (two-way valve) 991A, a regulator 991B, a pressure gauge 991C, an open-close valve (three-way valve) 991D, a mass flow controller 991E or the like. The inlet tube 993 is connected to a flow path port on the upstream side of the flow path (not shown) described above.

The present invention can be applied to various valve devices such as the open-close valves 991A and 991D and the regulator 991B described above.

### REFERENCE SIGNS LIST

1,1A: Valve device
2: Valve element
10: Actuator
11: Casing
12: Diaphragm presser
13: Holding ring
14: Diaphragm
15: Inner disk
15a1: Large diameter portion
15a2: Small diameter portion
15a3: Stepped surface
15b: Outer peripheral surface
15f1,15f2,15f3: Flat surface
15h: Flow path
16: Valve seat
16a: flow passage
16b1: Small diameter portion
16b2: Large diameter portion
16f: Sealing surface
16s: Seating surface
20: Valve body
20f1: Top surface
20f2: Bottom surface
20f3-20f6: Side surface
20h1: Screw hole
21: Primary flow path
21a: Seal holding portion
22: Accommodation recess
22a, 22b, 22c: Inner peripheral surface
22d: Bottom surface
24, 24A,24B: Secondary flow path
24a1, 24b1: Other end
25, 26: Branch flow path
25a,26b: Seal holding portion
30: Blocking member
50, 50A: Flow path assembly (valve seat support)
50a: Detour passage
50b1, 50b2: Outer peripheral surface
50b3: End surface
50f1: Support surface
51: Flow path member
51a: Fluid flow path
51e: Outer peripheral surface
51f: First sealing surface
52: Flow path member
52a: Fluid flow path
52e: Cylindrical portion
52e1: Inner peripheral surface
52e-c: Caulking portion
52f: Second sealing surface
52f2: Third sealing surface
53: Orifice plate
53A: Surface
53B: Back surface
53a: Orifice
54: First seal member
54f1: One end surface
54f2: Other end surface
54f3: Outer surface
55: Second seal member
60: Weld portion
700: Gas box
710: Tank
720: Valve
800: Processing chamber
900: Exhaust pump
991A-991E: Fluid device
992: Flow path block
993: Inlet tube
1000: Semiconductor manufacturing apparatus
A: Circle
A1: Upward direction
A2: Downward direction
B1, B2: Longitudinal direction
BS: Base plate
C1: Front side
C2: Rear side
Ct: Central axis
G1: Longitudinal direction (upstream side)
G2: Longitudinal direction (downstream side)
J1: Axis
W1, W2: Width direction

1. A flow path assembly comprising: a first flow path member and a second flow path member made of metal defining a fluid flow path connected to each other in a connecting portion;
a plate-like member provided between the first flow path member and the second flow path member and having a functional portion providing a specific action on a fluid flowing through the fluid flow path; and
an annular seal member made of resin provided between the first flow path member and the second flow path member;
the first flow path member having a first sealing surface for supporting one end surface of the annular seal member;
the second flow path member having a second sealing surface that is a flat surface for supporting a surface of the plate-like member, and a third sealing surface for supporting an outer peripheral surface of the annular seal member;
wherein the annular seal member is crushed by a force acting between the first flow path member and the second flow path member in the connecting portion, an other end surface of the annular seal member is pressed against a back surface of the plate-like member air-tightly or liquid-tightly, the one end surface of the annular seal member is pressed against the first sealing surface of the first flow path member air-tightly or liquid-tightly, and the outer peripheral surface of the annular seal member is pressed against the third sealing surface of the second flow path member air-tightly or liquid-tightly; and
the plate-like member is pressed by the other end surface of the annular seal member so that the surface of the plate-like member is pressed against the second sealing surface of the second flow path member air-tightly or liquid-tightly.

2. A flow path assembly comprising: a first flow path member and a second flow path member made of metal defining a fluid flow path connected to each other in a connecting portion;
a plate-like member provided between the first flow path member and the second flow path member and having a functional portion providing a specific action on a fluid flowing through the fluid flow path; and
an annular seal member made of resin provided between the first flow path member and the second flow path member;
the first flow path member having a first sealing surface for supporting one end surface of the annular seal member;
the second flow path member having a second sealing surface that is a flat surface for supporting a surface of the plate-like member, and a third sealing surface for supporting an outer peripheral surface of the annular seal member;
wherein the annular seal member is crushed by a force acting between the first flow path member and the second flow path member in the connecting portion, an other end surface of the annular seal member is pressed against the second sealing surface air-tightly or liquid-tightly, the one end surface of the annular seal member is pressed against the first sealing surface of the first flow path member air-tightly or liquid-tightly, and the outer peripheral surface of the annular seal member is pressed against the third sealing surface of the second flow path member air-tightly or liquid-tightly; and
the outer periphery of the plate-like member is welded air-tightly or liquid-tightly to the first flow path member or the second flow path member.

3. The flow path assembly according to claim 1, wherein the connecting portion comprises a connection formed by crimping.

4. The flow path assembly according to claim 1, wherein the annular seal member has a rectangular cross-sectional shape.

5. The flow path assembly according to claim 1, wherein the plate-like member comprises an orifice.

6. A valve device comprising the flow path assembly as defined in claim 1 incorporated in a valve body.

7-9. (canceled)

10. The flow path assembly according to claim 2, wherein the connecting portion comprises a connection formed by crimping.

11. The flow path assembly according to claim 2, wherein the annular seal member has a rectangular cross-sectional shape.

12. The flow path assembly according to claim 2, wherein the plate-like member comprises an orifice.

13. A valve device comprising the flow path assembly as defined in claim 2 incorporated in a valve body.
